(19) United States
(12) Patent Application Publication
(10) Pub. No.: US 2007/0096088 A1
(43) Pub. Date: May 3, 2007

(54) Organic transistor and display device

(76) Inventors: Takanori Tano, Kanagawa (JP); Koei Suzuki, Kanagawa (JP); Ikue Kawashima, Kanagawa (JP); Yoshikazu Akiyama, Kanagawa (JP)

Correspondence Address: COOPER & DUNHAM, LLP, 1185 AVENUE OF THE AMERICAS, NEW YORK, NY, 10036, US

(21) Appl. No.: 11/590,212

(22) Filed: Oct. 30, 2006

(30) Foreign Application Priority Data
Nov. 2, 2005 (JP) 2005-319691
Aug. 4, 2006 (JP) 2006-213403

(51) Int. Cl. H01L 29/08

(52) U.S. Cl. 257/40

(57) ABSTRACT

An organic transistor including a stacked insulating film in which an insulating layer and a wettability control layer are stacked in order is provided, wherein the wettability control layer includes a material whose surface energy can be changed by irradiation with an ultraviolet ray and a transmittance of the ultraviolet ray for irradiation therethrough is 10% or greater.

### BACKGROUND OF THE INVENTION

1. Field of the Invention

The present invention relates to an organic transistor and a display device.

2. Description of the Related Art

Recently, an organic thin-film transistor using an organic semiconductor material has been actively studied. As an advantage of an organic thin-film transistor, for example, the flexibility thereof, sizing up of the surface area thereof, simplification of a production process due to a simple layer structure thereof, and cost down of a production apparatus therefore can be listed. As a result, production thereof which is less expensive than that of a conventional Si-based semiconductor device can be provided. Further, a thin film or a circuit can be easily formed by, for example, a printing method, a spin-coat method, and a dipping method.

As one parameter for indicating the characteristic of an organic thin-film transistor, an on/off ratio (Iₒₙ/I_{off}) of electric current is provided. In an organic thin-film transistor, electric current I_{ds} conducting between a source electrode thereof and a drain electrode thereof in a saturation region thereof is provided by formula (1),

$${I}_{ds} = \frac{μ {C}_{in} {W ( {V}_{G} - {V}_{TH} )}^{2}}{2 L} \qquad ( 1 )$$

wherein μ is a field-effect mobility, Cᵢₙ (=εε₀/d) is the capacitance per unit area of a gate insulting film thereof (ε is the relative dielectric constant of the gate insulating film, ε₀ is the vacuum electric constant, and d is the thickness of the gate insulating film.), W is a channel width, L is a channel length, V_{G} is a gate voltage, and V_{TH} is a threshold voltage.

Formula (1) indicates that it is effective, for example, to increase the field-effect mobility, to decrease the channel length, and to increase the channel width, in order to increase on-electric current.

The field-effect mobility greatly depends on material characteristics and a material for increasing the field-effect mobility has been developed.

On the other hand, since the channel length depends on the structure of the device, the structure of the device has been improved. In order to decrease the channel length, the space between the source electrode and the drain electrode is reduced. As a method for precisely fabricating a device in which the space between the source electrode and the drain electrode is small, photolithography is known which has been used as a production process for a conventional Si-based semiconductor device.

The photolithography processes are as follows.

(1) A photoresist layer is applied on a thin-film layer provided on a substrate (resist application).

(2) Solvent is removed by heating (pre-bake).

(3) Irradiation with ultraviolet rays is conducted through a hard mask which is patterned in accordance with pattern data using a laser or an electron beam (light exposure).

(4) The resist on an exposed part is removed by using an alkali solution (development).

(5) The resist on an unexposed part (patterned part) is cured by heating (post-bake).

(6) The thin-film layer on a resist-free part is removed by dipping in an etching liquid or exposure to an etching gas (etching).

(7) The resist is removed by using an alkali solution or an oxygen radical (resist removal).

As described above, after each thin film layer is formed, an active element can be fabricated by repeating the processes described above according to need, but expensive equipment and a long process line cause the cost to be higher.

On the other hand, formation of an electrode pattern has been tried by a printing method using, for example, ink jet, in order to reduce the production cost (see JP-A-2004-006395, JP-A-2004-031933, JP-A-2004-141856, and JP-A-2004-297011.).

The usage rate of a material in ink jet printing is high since the electrode pattern can be directly formed. Therefore, there is a possibility of realizing simplification or costing down of a production process. However, since it is difficult to reduce the ejection quantity in ink jet printing, it is difficult to form a pattern equal to or less than 50 μm if the landing precision depending on a mechanical error, etc., is taken into consideration.

Then, the surface on which ink is landed has been improved for attainment of high fineness. A method for stacking films made of a material whose surface free energy can be changed by means of ultraviolet rays, on a gate insulating film, is disclosed in the extended abstract of the 52nd Spring Meeting of the Japan Society of Applied Physics and Related Societies, p. 1510, 31p-YY-5. In this method, a part with low surface free energy can be fabricated on a gate insulating film by irradiating an electrode fabricating part with ultraviolet rays through a mask. Next, when an electrode material of water-soluble ink is ink-jet-coated, an electrode is formed on the part with high surface free energy and a highly fine electrode pattern can be formed on the gate insulating film.

In this method, functional separation to an insulating property retaining layer and a surface free energy changeable layer is attained, but there is a problem such that the insulating film is damaged and the insulating property is degraded since the gate insulating film is irradiated with the ultraviolet rays.

In the extended abstract of the 52nd Spring Meeting of the Japan Society of Applied Physics and Related Societies, p. 1510, 31p-YY-5, the problem is tried to be avoided by making the thickness of the gate insulating film be approximately 1 μm, but, as seen in formula (1), if the thickness d of the gate insulating film is increased, the electric current Ids decreases. Thus, it is necessary to increase the applied voltage V_{g} and it is difficult to make a device with low electric power consumption.

As described above, since the insulating property of the gate insulating film is degraded by ultraviolet ray irradiation to form an electrode pattern, it is necessary to reduce the damage of the gate insulating film which is caused by ultraviolet ray irradiation.

Therefore, it could be desired to provide an organic transistor having a-gate insulating film with a good insulating property and capable of reducing electric power consumption and a display device having the organic transistor.

### SUMMARY OF THE INVENTION

According to one aspect of the present invention, there is provided an organic transistor including a stacked insulating film in which an insulating layer and a wettability control layer are stacked in order, wherein the wettability control layer includes a material whose surface energy can be changed by irradiation with an ultraviolet ray and a transmittance of the ultraviolet ray for irradiation therethrough is 10% or greater.

### BRIEF DESCRIPTION OF THE DRAWINGS

Other objects, features and advantages of the present invention will become more apparent from the following detailed description when read in conjunction with the accompanying drawings, in which:

FIG. 1 is a cross-section diagram showing one example of an organic transistor according to the present invention;

FIG. 2 is a diagram illustrating the wettability of liquid on the surface of a solid;

FIG. 3 is a diagram showing one example of a Zisman plot for a wettability control layer;

FIG. 4 is a diagram showing one example of a production process of an organic transistor according to the present invention;

FIG. 5 is a diagram showing one example of a device having a plural organic transistors according to the present invention, wherein (a) is a cross section diagram thereof and (b) is a plan view thereof;

FIG. 6 is a cross section diagram showing one example of a display device according to the present invention;

FIG. 7 is a diagram showing the relationship of the specific resistance of a stacked insulating film to the transmittance of ultraviolet rays through a polyimide film (JALS-2021);

FIG. 8 is a diagram showing the variation of the contact angle of water on a polyimide film (JALS-2021);

FIG. 9 is a diagram showing the variation of the contact angle of water on a polyimide film (PI-101); and

FIG. 10 is a diagram showing the relationship of the insulating property of a stacked insulting film to the film thickness thereof.

### DETAILED DESCRIPTION OF THE PREFERRED EMBODIMENTS

Next, the best mode of embodiments for implementing the present invention is described with reference to the drawings.

An organic transistor according to the present invention has at least a stacked insulating film (a gate insulating film) in which an insulating layer and a wettability control layer are stacked in order, wherein the wettability control layer contains a material whose surface energy can be changed by irradiation with ultraviolet rays and the transmittance of the ultraviolet rays for irradiation is 10% or greater. This makes it possible to form a highly fine electrode pattern and can form a stacked insulating film with a good insulating property which is less damaged under irradiation with ultraviolet rays, when an organic transistor according to the present invention is fabricated using an ink jet method. As a result, an organic transistor with a good characteristic can be obtained and a production process thereof can be simplified.

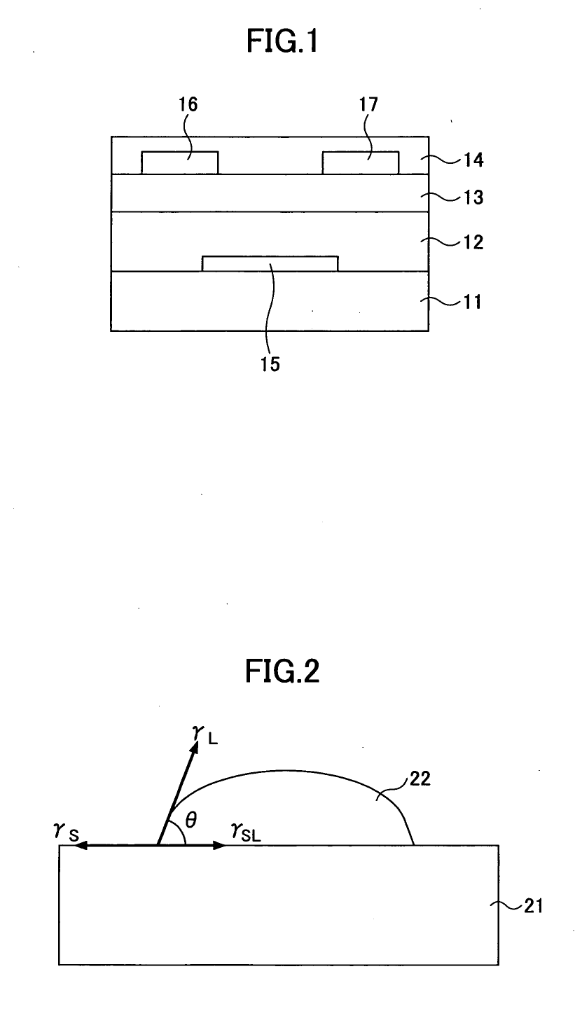

FIG. 1 shows one example of an organic transistor according to the present invention. On a substrate 11, a stacked insulating film in which an insulating layer 12 and a wettability control layer 13 are stacked and an organic semiconductor film 14 are stacked in order as a gate insulating film, wherein a gate electrode 15 is provided between the substrate 11 and the insulating layer 12 and a source electrode 16 and a drain electrode 17 are provided between the wettability control layer 13 and the organic semiconductor layer 14. Then, the wettability control layer 13 is made of a material whose surface energy can be changed by application of energy such as heat and ultraviolet rays thereto and the difference between the surface energy of an ultraviolet ray irradiated area and that of ultraviolet ray non-irradiated area is 15 mN/m or greater. Further, the transmittance of the ultraviolet rays for irradiation through the wettability control layer 13 is 10% or greater. Thus, degradation of the insulating property of the stacked insulating film can be suppressed. Additionally, the insulating property of the insulating layer is commonly higher than that of the wettability control layer. Herein, an insulating property being high means that a volume resistivity is high.

In the present invention, the film thickness of the wettability control layer 13 is preferably 4 nm or greater and 200 nm or less. If the film thickness of the wettability control layer 13 is less than 4 nm, the continuity of the film may be degraded and a film having surface energy sufficient to conduct patterning may not be able to be formed. Also, if the film thickness of the wettability control layer 13 is greater than 200 nm, the ratio of the film thickness of the wettability control layer 13 to the film thickness of the stacked insulating film may be high and the insulating property of the stacked insulating film may be degraded.

The wettability control layer contains a material whose surface energy can be changed by irradiation with ultraviolet rays, wherein the absorption coefficient of a material for forming the wettability control layer is preferably greater that of a material for forming the insulating layer in order to suppress damage of the insulating layer which is caused by ultraviolet ray radiation.

In the present invention, at least the wettability control layer is stacked on the insulating layer in the stacked insulating film, wherein a source electrode and a drain electrode are preferably formed on the wettability control layer. Additionally, the stacked insulating film may have a stacked structure of three or more layers. Also, the insulating film may be combined with a wettability control layer.

In the present invention, the film thickness of the stacked insulating film is preferably 50 nm or greater and 750 nm or less. Then, the film thickness is the sum of the film thickness of an insulating layer obtained with film uniformity and no gate leak and the film thickness of a wettability control layer, but if the film thickness of the stacked insulating film is less than 50 nm, the film uniformity or continuity may be degraded. As a result, short-circuit may be generated and the degradation of the insulating property may be caused.

The reason why the film thickness of the stacked insulating film (gate insulating film) is preferably 750 nm or less is described below.

The field-effect mobility μ of an organic semiconductor material, particularly, a polymeric material capable of applying a printing fabrication method, is approximately 2.5×10⁻³ cm²/V-sec. The relative dielectric constant ε of an organic material used for the gate insulating film is commonly 3 or greater and 4 or less, which is 3.7 for a polyimide. Although there exists a material with high relative dielectric constant ε such as cyanoethylpullulan, since the material with high relative dielectric constant ε has a low insulating property thereof and is not preferable as a material for the insulating film.

When the organic transistor is applied to a driving device of a highly fine display (for example, an electrophoretic device), the number of scanning lines is greater than 200 in order to attain 200 ppi in regard to a size such as A4, and therefore, scanning time per 1 line is 500 μsec or less. At 200 ppi, the surface area of 1 picture element is 125 μm² and the film thickness of a display device is approximately 50 μm as the size of a capsule for electrophoresis is taken into consideration. When a picture element of the display is made of a white or black color displaying material, a white particle is made of titanium oxide and a black particle is made of carbon black.

The relative dielectric constant εᵣ of titanium oxide is greater than the relative dielectric constant of carbon black and is 100. When a driving voltage is 20 V, an electric charge CV₀ necessary to drive 1 picture element can be obtained by formula (2),

$${CV}_{0} = {ɛ}_{r} {ɛ}_{0} ( \frac{S}{t} ) {V}_{0} \qquad ( 2 )$$

wherein εᵣ is the relative dielectric constant of a display particle, ε₀ is the vacuum electric constant, C is the capacitance of a picture element, V₀ is a driving voltage, S is the surface area of a picture element, and t is the film thickness of a picture element. As substitution with the values described above are made, CV₀ is 5.5×10⁻¹²[C]. When frames are switched for 0.5 seconds, writing time of 1 line is 0.5 [seconds]/2000=250 [μsec]. Therefore, a driving electric current I_{ds} necessary for 1 picture element is I_{ds}=5.5 [pC]/250 [μsec]=22 [nA]. In formula (1), as substitution is performed with respect to I_{ds} (=22 [nA]), the ratio of a channel width to a channel length W/L (=10; approximately 10 as the size of an electrode of a picture element is taken into consideration), a driving voltage V_{G} (=20 V), the relative dielectric constant ε of a gate insulating film (polyimide film) (=3.7), and a field-effect mobility μ (=2.5×10⁻³ [cm²/V·sec]), the thickness d of the gate insulating film is 750 nm.

Since the square of a driving voltage and the film thickness are in a linear relationship, the film thickness of a gate insulating film is preferably 750 nm or less in order to decrease the driving voltage, that is, to fabricate an organic transistor with low electric power consumption.

In the present invention, the stacked insulating film preferably contains a polymeric material. As a polymeric material, there can be provided, for example, polyimides, siloxanes, silsesquioxane, poly(vinylphenol), polycarbonates, fluorine-containing resins, and poly(para-xylylene).

In the present invention, the wettability control layer may be composed of a single material or may be composed of two or more materials. When it is composed of two or more materials, a wettability control layer excellent in the insulating property thereof and also excellent in the surface energy change thereof can be formed by, specifically, mixing a material with a large surface energy change into a material with a large insulating property. Also, since the use of a material having a large surface energy change but having a low film formation property is allowed, materials which can be selected are increased. Specifically, where one material is difficult to form a film since the material has a large surface energy change and the cohesive force thereof is strong, the wettability control layer can be formed by mixing the other material having a good film formation property.

In the present invention, the source electrode and the drain electrode can be formed by, for example, heating or applying ultraviolet ray radiation to, a liquid containing an electrically conductive material so as to cure it.

Also, as a liquid containing an electrically conductive material, there can be used, for example, solutions in which an electrically conductive material is dissolved in a solvent, precursors of an electrically conductive material, solutions in which a precursor of an electrically conductive material is dissolved in a solvent, dispersion liquids in which an electrically conductive material is dispersed in a dispersive medium, and dispersion liquids in which a precursor of an electrically conductive material is dispersed in a dispersive medium. Specifically, there can be provided, for example, dispersion liquids in which a metal fine particle of Ag, Au, Ni, etc., is dispersed in an organic dispersive medium or water, aqueous solutions of a doped PANI (poly(aniline)), and aqueous solutions of the electrically conductive polymer in which PSS (poly(styrenesulfonic acid)) is doped in a PEDOT (poly(ethylenedioxythiophene)).

As described above, preferably, the wettability control layer contains a material whose surface energy can be changed by irradiation with ultraviolet rays and the degree of change of the surface energy between before and after the irradiation with ultraviolet rays is large. As a predetermined area of such a wettability control layer is irradiated with ultraviolet rays, a pattern with different surface energies can be formed which is composed of a high surface energy part and a low surface energy part. Accordingly, the liquid containing an electrically conductive material easily adheres to the high surface energy part (a lyophilic property) and hardly adheres to the low surface energy part (a lyopobic property). Therefore, the liquid containing an electrically conductive material selectively adheres to the high surface energy part which is lyophilic according to a pattern and is further solidified, so that a source electrode and a drain electrode can be formed.

Next, the wettability (adhesion property) of liquid on the surface of a solid is described below. FIG. 2 shows a situation such that a liquid drop 22 has a contact angle θ to the surface of a solid 21 and is in an equilibrium condition. Then, Young's formula
γ_{S}=γ_{SL}+γ_{L} cos θ
is satisfied. Herein, γ_{S} is surface tension of the solid 21, γ_{SL} is interfacial tension between the solid 21 and the liquid drop 22, and γ_{L} is surface tension of the liquid drop 22. Additionally, the surface tension is substantially synonymous with surface energy and has the same value.

The contact angle θ can be measured by a liquid drop method. As a liquid drop method, there are provided a tangential method in which a liquid drop 22 is observed a microscope and a cursor line observed in the microscope is located on a contact point of the liquid drop 22 so as to read the angle, a θ/2 method in which when a cross cursor is located on an apex of the liquid drop 22 and one end thereof is located on a contact point of the liquid drop 22 and the solid 21 the angle of the cursor line is doubled so as to obtain it, and a three-points click method in which the liquid drop 22 is displayed on a monitor screen and one point on a circumference (preferably, an apex) and contact points of the liquid drop 22 and the solid sample 21 (two points) are clicked for computer processing. Then, the measurement precisions become higher in the order of a tangential line method, a θ/2 method, and a three-points click method.

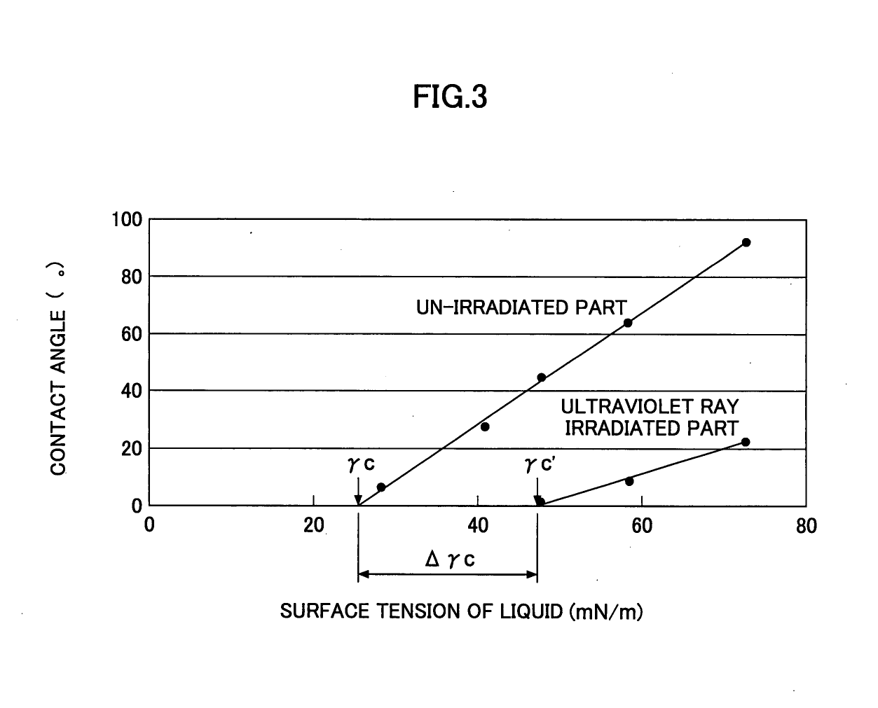

FIG. 3 shows a result of conducting Zisman plots for an ultraviolet ray un-irradiated part and an ultraviolet ray irradiated part wherein a wettability control layer made of JALS-2021 (produced by JSR) is used. From FIG. 3, it can be seen that the critical surface tension γ_{C} on the ultraviolet ray un-irradiated part is approximately 24 mN/m and the critical surface tension γ_{C}, on the ultraviolet ray irradiated part is approximately 45 mN/m, whereby the difference Δγ_{C} therebetween is approximately 21 mN/m.

In order that liquid containing an electrically conductive material certainly adheres to a high surface energy part which is lyophilic in accordance with a pattern made of a high surface energy part and a low surface energy part, a surface energy difference being large, that is, the difference between critical surface tensions ‘Δγ_{C}’s being large is needed.

Wettability control layers made of various kinds of materials are formed on a glass substrate and FIG. 1 shows the evaluation results of ‘Δγ_{C}’s and selective adhesion properties of an aqueous solution of PEDOT (poly(ethylenedioxythiophene))/PSS (poly(styrenesulfonic acid)).

TABLE 1

| | | Selective adhesion |
|---|---|---|
| Material | Δγ_{c} | property |
| A: poly(vinylphenol) | 6 mN/m | Frequent adhesion on |
| | | an irradiated part |
| B: polyimide | 10 mN/m | Slight adhesion on an |
| | | irradiated part |
| C: polyimide with a | 21 mN/m | No adhesion on an |
| side chain | | irradiated part |

The selective adhesion property was evaluated by dropping a PEDOT/PSS aqueous solution onto an area containing the interface of patterns of an ultraviolet ray irradiated part and an ultraviolet ray un-irradiated part, removing extra liquid, and subsequently, observing the presence or absence of the adhesion pf the PEDOT/PSS aqueous solution to the ultraviolet ray un-irradiated part (a pattern failure). Additionally, material A is Markalinker M (available from Maruzen Petrochemical), material B is SP-710 (available from Toray industries, Inc.), and material C is JALS-2021 (available from JSR Corporation).

It can be seen from FIG. 1 that the Δγ_{C} of the wettability control layer is preferably 15 mN/m or greater.

Additionally, as the critical surface tension is 20 mN/m or less, the critical surface tension γ_{C} of an ultraviolet un-irradiated part of the wettability control layer is preferably 20 mN/m or greater when an organic semiconductor layer is formed by coating since most of solvents are repelled.

In the present invention, the wettability control layer preferably contains a polymeric material having a hydrophobic group in a side chain thereof. Specifically, a compound can be provided in which a side chain having a hydrophobic group bonds to a main chain having a skeleton such as a polyimide and a poly((meth)acrylic acid ester) directly or via a linking group.

As a hydrophobic group, alkyl groups having a terminal structure such as —CH₂CH₃, —CH(CH₃)₂, and —C(CH₃)₃ can be provided. The hydrophobic group preferably has a long carbon chain and more preferably a carbon chain whose carbon number is 4 or greater, in order to facilitate the orientation of molecular chains to one another. The hydrophobic group may be a straight chain structure or a branched chain structure, and a straight chain structure is preferable. The alkyl group may have a halogen group, a cyano group, a phenyl group, a hydroxyl group, a carboxyl group, or a phenyl group substituted with a linear-chain, branched-chain or cyclic alkyl group or alkoxy group whose carbon number is 1-12. Additionally, it is considered that the smaller the number of hydrophobic group(s) contained in the polymeric material is, the smaller the surface energy (critical surface tension) of a wettability control layer is and the more lyophobic it is. It is deduced that such a polymeric material increases the critical surface tension and is lyophilic since a part of bonding is broken or the orientation is changed by ultraviolet ray irradiation.

As the formation of an organic semiconductor layer on the wettability control layer is taken into consideration, the polymeric material having a hydrophobic group in a side chain is preferably a polyimide. Polyimides are excellent in the solvent resistance and heat resistance thereof, and therefore, the swelling caused by a solvent or the generation of a crack cased by the temperature change thereof at the time of baking when an organic semiconductor layer is formed on the wettability control layer.

Also, when the wettability control layer is composed of two or more kind of materials, the two or more kinds of materials are preferably polyimides as the heat resistance, solvent resistance and compatibility thereof are taken into consideration.

In the present invention, as a hydrophobic group contained in a side chain of a polyimide, functional groups can be provided which are represented by the following five kinds of chemical formulas. 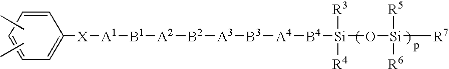
wherein X is a methylene group or an ethylene group, A¹ is a 1,4-cyclohexylene group, a 1,4-phenylene group, or a 1,4-phenylene group substituted with 1-4 fluoro groups, each of A², A³ and A⁴ is independently a single bond, a 1,4-cyclohexylene group, 1,4-phenylene group, or a 1,4-phenylene group substituted with 1-4 fluoro groups, each of B¹, B² and B³ is independently a single bond or an ethylene group, B⁴ is an alkylene group whose carbon number is 1-10, each of R³, R⁴, R⁵, R⁶ and R⁷ is independently an alkyl group whose carbon number is 1-10, and p is an integer equal to or greater than 1. 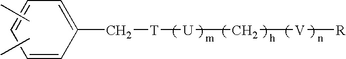
wherein each of T, U and V is independently a phenylene group or a cyclohexylene group, an arbitrary hydrogen atom of which-ring may be substituted with an alkyl group whose carbon number is 1-3, a fluorine-substituted alkyl group whose carbon number is 1-3, a fluoro group, a chloro group, or a cyano group, each of m and n is independently an integer of 0-2, h is an integer of 0-5, R is a hydrogen atom, a fluoro group, a chloro group, a cycano group or a monovalent organic group, and two ‘U’s when m is 2 or two ‘V’s when n is 2 may be identical or different. 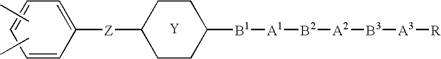
wherein Z is a methylene group, a fluoromethylene group, a difluoromethylene group, an ethylene group, or difluoromethyleneoxy group, ring Y is a 1,4-cyclohexylene group or a 1,4-phenylene group whose 1-4 hydrogen atoms may be replaced by a fluoro group(s) or a methyl group(s), each of A¹, A², and A³ is independently a single bond, a 1,4-cyclohexylene group or 1,4-penylene group whose 1-4 hydrogen atoms may be replaced by a fluoro group(s) or a methyl group(s), each of B¹, B², and B³ is independently a single bond, an alkylene group whose carbon number is 1-4, an oxy group, or an oxyalkylene group whose carbon number is 1-3, R is a hydrogen atom, an alkyl group whose arbitrary methylene group may be replaced by a difluoromethylene group and whose carbon number is 1-10, or an alkoxy group whose 1 methylene group may be replaced by a difluoromethylene group and whose carbon number is 1-9, or an alkoxyalkyl group, and the bonding position of an amino group on the benzene ring is arbitrary. Herein, when Z is a methylene group, not all the B¹, B² and B³ is simultaneously alkylene groups whose carbon number is 1-4, then, when Z is a methylene group and ring Y is a 1,4-phenylene group, none of A¹ and A² is a single bond, and when Z is a difluoromethyleneoxy group, ring Y is not a 1,4-cyclohexylene group. 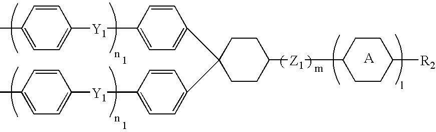
wherein R² is a hydrogen atom or a alkyl group whose carbon number is 1-12, Z₁ is a methylene group, m is 0-2, ring A is a phenylene group or a cyclohexylene group, l is 0 or 1, each Y₁ is independently an oxy group or a methylene group, and each n₁ is independently 0 or 1. 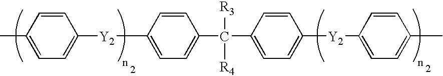
wherein, each Y₂ is independently an oxy group or a methylene group, each of R₃ and R₄ is independently a hydrogen atom or an alkyl group or perfluoroalkyl group whose carbon number is 1-12, at least one of which is an alkyl group or perfluoroalkyl group whose carbon number is 3 or greater, and each n₂ is independently 0 or 1.

The details of these materials are described in, for example, Japanese Laid-Open Patent Application No. 2002-162630, Japanese Laid-Open Patent Application No. 2003-096034, and Japanese Laid-Open Patent Application No. 2003-267982, the entire contents of which Japanese patent applications are hereby incorporated by reference. Also, for a tetracarboxylic dianhydride constituting the skeleton of a main chain of a polyimide having a hydrophobic group in a side chain, there can be used, for example, aliphatic materials, alicyclic materials and aromatic materials. Specifically, there can be provided, for example, pyromellitic dianhydride, cyclobutanetetracarboxylic dianhydride and butanetetracarboxylic dianhydride. In addition, there can be also used, for example, materials described in Japanese Laid-Open Patent Application No. 11-193345, Japanese Laid-Open Patent Application No. 11-193346, and Japanese Laid-Open Patent Application No. 11-193347 in detail, the entire contents of which are hereby incorporated by reference.

The polyimide having a hydrophobic group in a side chain may be singularly used or may be used by mixing another material. Herein, when a mixture is used, it is preferable that a mixed material is also a polyimide as the heat resistance, solvent resistance, and compatibility thereof is taken into consideration. Also, there can be used a polyimide which has a hydrophobic group except the functional groups represented by the five kinds of chemical formulas described above.

As a polyimide has a hydrophobic group in a side chain, the characteristic of an interface thereof with an organic semiconductor layer can be made be good. The interface characteristic being good means the occurrence of a phenomenon such that when the organic semiconductor is amorphous (a polymer), the interface level density decreases and the field-effect mobility increases, and when the organic semiconductor is a polymer and has a side chain such as a long-chain alkyl group, the orientation thereof is controlled and the molecular axes of a π-conjugate main chain can be generally oriented along one direction so that the field-effect mobility increases.

As a method for applying the liquid containing an electrically conductive material onto the surface of an wettability control layer, there can be used, for example, a spin-coat method, a dip-coat method, a screen-printing method, an offset printing method and an ink jet method, wherein the ink jet method, which can provide a smaller liquid drop, is particularly preferable in order to easily influence the surface energy of the wettability control layer. When a normal head at a level used in a printer is used, the resolution of an ink jet method is approximately 30 μm and the precision of positioning is approximately ±15 μm, but a finer pattern can be formed using the surface energy difference on the wettability control layer.

For the organic semiconductor layer, there can be used, for example, an organic semiconductor such as organic lower molecular-weight molecules such as pentacene, anthracene, tetracene and phthalocyanine, poly(acetylene)-type and electrically conductive polymers, poly(phenylene)-type and electrically conductive polymers such as poly(para-phenylene) and derivatives thereof and poly(phenylene vinylene) and derivatives thereof, heterocyclic and electrically conductive polymers such as poly(pyrrole) and derivatives thereof, poly(thiophene) and derivatives thereof and poly(furan) and derivatives thereof, and ionic and electrically conductive polymers such as poly(aniline) and derivatives thereof.

Also, the wettability control layer is irradiated with ultraviolet rays whereby a high resolution can be obtained by an operation in atmosphere and damage on an insulating film can be reduced.

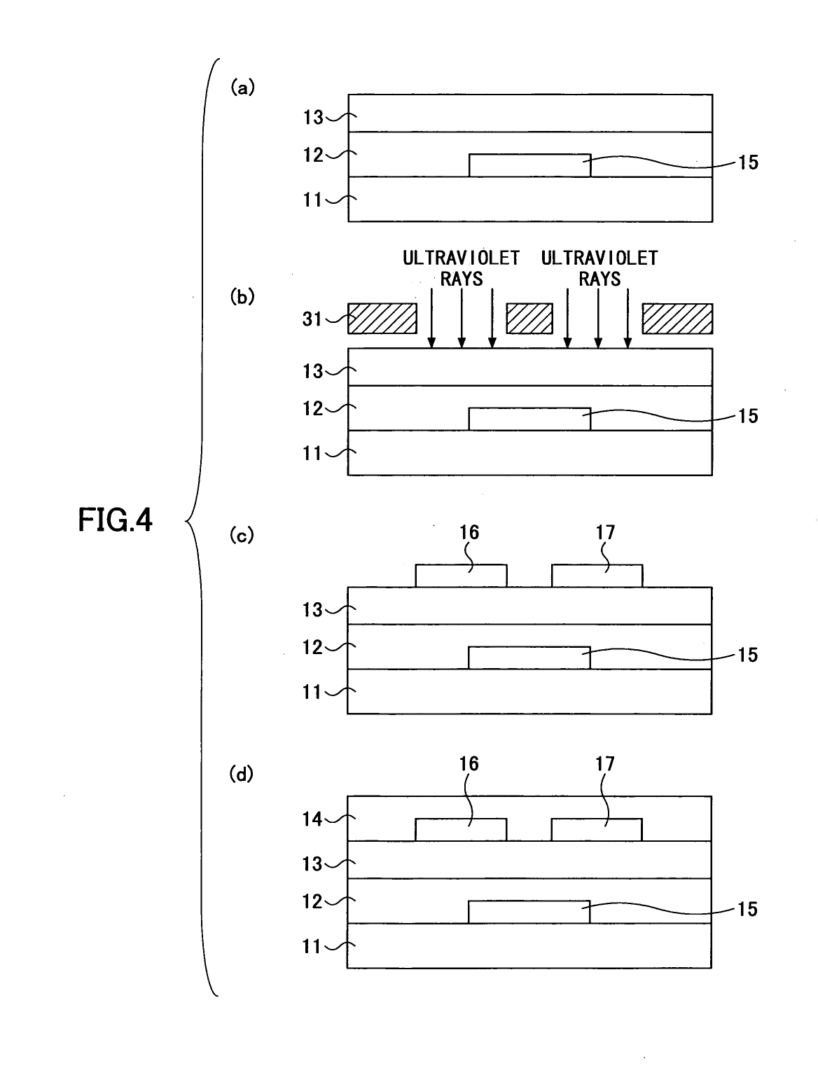

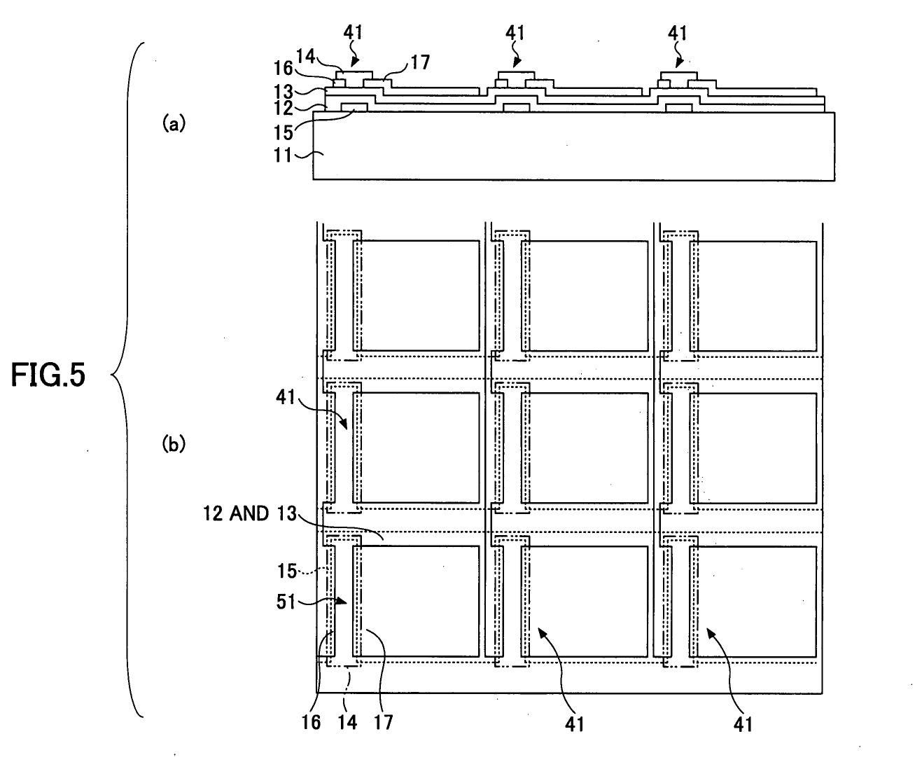

FIG. 4 shows one example of a process of fabricating an organic transistor according to the present invention.

First, as shown in FIG. 4(a), a gate electrode 15 is formed on a substrate 11 by, for example, a vapor deposition method, a CVD method, a spin-coat method, a dip-coat method, and a cast method. For the gate electrode 15, each kind of electrically conductive thin film can be used and after the film formation is conducted over the entire surface of the substrate 11, patterning may be performed by a common photolithography method or a micro-contact printing method, or direct patterning may be conducted by feeding the liquid containing an electrically conductive material using an ink jet method, etc. Additionally, as a material for the substrate 11, there can be used, for example, glass, plastics such as poly(carbonate)s, poly(allylate) and poly(ethersulfone)s, a silicon wafer, and metals.

Next, an insulating layer 12 is formed by, for example, a vapor deposition method, a CVD method, a spin-coat method, a dip-coat method, and a cast method. For the insulating layer 12, inorganic insulating materials and organic insulating materials can be applied, and since a formation method which provides a little damage on the substrate 11 can be used, for example, SiO₂ which can be formed by a vapor deposition method, water-soluble poly(vinylalcohol)s, alcohol-soluble poly(vinylphenol)s, and fluorine-containing solvent-soluble perfluoropolymers are preferable.

Further, a wettability control layer 13 is formed. The wettability control layer 13 is made of a material whose critical surface tension is increased by irradiation with ultraviolet rays so as to change from a lower surface energy state (lyophobic state) to a higher state (lyophilic state). A preferable structure of such a material is as described above, and the wettability of a material whose main chain is composed of a polyimide skeleton and whose side chain has a long-chain alkyl group is particularly greatly changed by irradiation with ultraviolet rays. A solution or dispersion liquid in which a polymeric material or a precursor thereof, which has such a structure, is dissolved or dispersed in an organic solvent, etc., is applied on the insulating layer 12 by using, for example, a spin coat method, a dip-coat method, a wire-bar-coat method, and a cast method and is dried, so as to form a wettability control layer 13.

Next, as shown in FIG. 4(b), the surface of the wettability control-layer 13 is irradiated with ultraviolet rays through a mask 31. Accordingly, a pattern composed of a lower surface energy part and a higher surface energy part is formed. As an ultraviolet ray, it is preferable to contain light whose wavelength is 100-300 nm.

Next, as shown in FIG. 4(c), when liquid containing an electrically conductive material is provided, for example, by an ink jet method, on the wettability control layer 13 on which a pattern has been formed, electrically conductive layers (a source electrode 16 and a drain electrode 17) are formed on the higher surface energy part.

Finally, as shown in FIG. 4(d), an organic semiconductor layer 14 is formed by applying and drying a solution in which a polymeric semiconductor or a precursor thereof is dissolved, for example, by a spin-coat method, a dip-coat method, a wire-bar-coat method, and a cast method.

Additionally, before the gate electrode 15 is formed, a second wettability control layer (which is not shown in the figure) different from the wettability control layer 13 may be provided on the substrate 11 and used for the patterning of the gate electrode 15. Also, although the organic semiconductor layer 14 is formed over the entire surface of the substrate 11, patterning may be conducted in the form of an island containing at least a channel region. As a method for it, there can be used, for example, a mask vapor deposition method, a screen printing method, an ink jet method, and a micro-contact printing method.

FIG. 5 shows one example of a device having plural organic transistors according to the present invention. Herein, (a) is a cross section diagram thereof and (b) is a plan view showing the configuration of electrodes, etc. Herein, the organic transistor 41 shown in FIG. 1 is used.

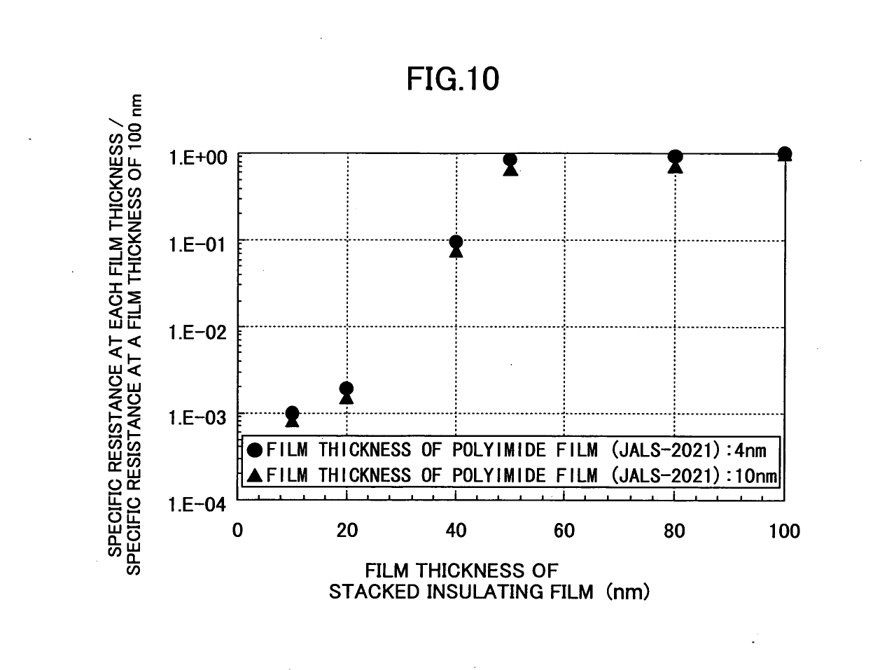

On a substrate 11, plural sets of a gate electrode 15, an insulating layer 12, a wettability control layer 13, a source electrode 15 and a drain electrode 16 are patterned and formed in the form of a two-dimensional array by a method similar to that of FIG. 10.

Additionally, the gate electrode 15 of each organic transistor 41 is connected to a bus line so as to be driven by a driver IC for a scanning signal, and similarly, the source electrode 16 is also connected to a bus line so as to be driven by a driver for a data signal.

Next, the subject device is completed by forming the organic semiconductor layer 14 into, for example, an island shape containing a channel region by using a micro-contact printing method. Additionally, the micro-contact printing method is a method such that a stamp of PDMS (polydimethylsiloxane) is fabricated by using a master which is pattern-formed by means of lithography and liquid containing an organic semiconductor material adheres to a convex part and is transcribed onto the substrate 11. Since the organic semiconductor layer 14 is formed into an island shape containing a channel region, no leak of electric current to an adjacent element part occurs.

Additionally, the organic transistor 41 is preferably covered by a passivation film in order to suppress the degradation of the characteristic of the organic transistor 41 which is caused by oxygen, a water content, radiation rays, etc., although it is not shown in FIG. 5.

For the passivation film, there can be used, for example, aluminum nitride, silicon nitride, and silicon nitride oxide. These can be formed by a CVD method, an ion plating method, etc.

A display device according to the present invention uses an organic transistor according to the present invention as an active element. As such an active matrix display devoice, a display panel can be provided which can be obtained by combining the organic transistor according to the present invention and a picture element displaying element. Such a display panel can be excellent in flexibility thereof and be fabricated inexpensively.

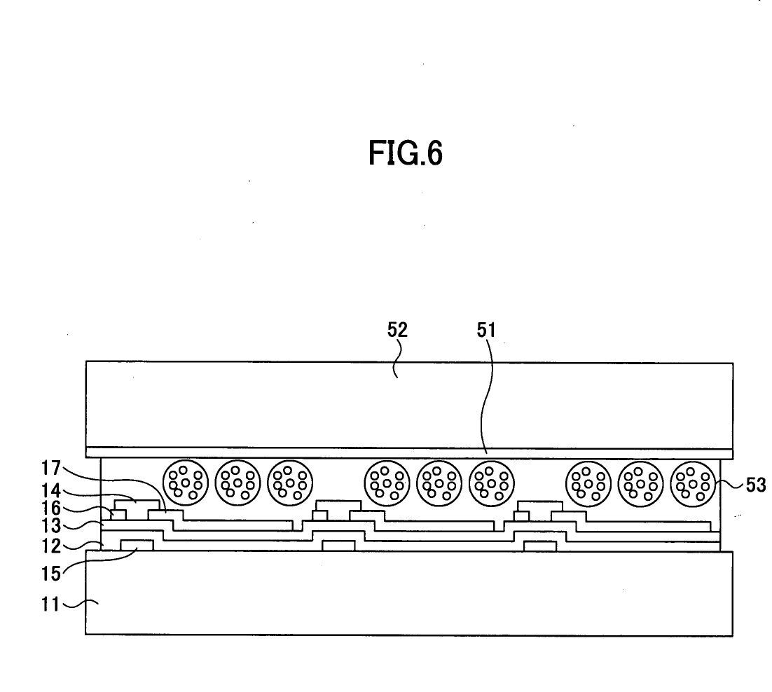

FIG. 6 shows one example of a display device according to the present invention. Picture element displaying elements 53 are provided between the device shown in FIG. 5 and a substrate 52 having a transparent and electrically conductive film 51 and the picture element displaying device 53 on the drain electrode 17 which also acts as a picture element electrode is switched by organic transistors. As a substrate 52, there can be used, for example, glass and plastics such as polyesters, polycarbonates, polyallylates and poly(ethersulfone)s. As a picture element displaying element 53, there can be provided, for example, a liquid crystal display element, an electrophoretic display element and an organic EL element.

Since the liquid crystal display element is driven by means of electric field, the electric power consumption thereof is small, and since the driving voltage thereof is low, the driving frequency of the organic transistor can be increased so as to be suitable for a large capacity display. As a display system of the liquid crystal display element, there can be provided, for example, TN liquid crystals, STN liquid crystals, guest-host-type liquid crystals and polymer-dispersed liquid crystals (=PDLC), wherein a PDLC is preferable since it is reflection-type and a bright and white display can be obtained.

The electrophoretic display element is composed of a dispersion liquid in which particles exhibiting a first color (for example, white color) are dispersed in a colored dispersion medium exhibiting a second color, wherein the location of the particles exhibiting the first color in the dispersion medium can be changed by charging them in the colored dispersion medium, that is, the action of electric field, and accordingly, exhibited color can be changed. According to the display system, bright display with wide angular field of view can be attained and since a display memory can be provided, particularly, it is preferably used from the viewpoint of electric power consumption. Then, a display device which can attain a stable display operation can be easily fabricated by covering the dispersion liquid described above with a polymeric film so as to form a microcapsule. The microcapsule can be fabricated by a publicly-known method such as a coacervation method, an in-situ polymerization method and an interfacial polymerization method. As a white color particle, particularly, titanium oxide is preferably used, and surface treatment or complexation with another material is applied according to need. As a dispersion medium, it is preferable to use an organic solvent with a high resistivity such as aromatic hydrocarbons such as benzene, toluene, xylene, and naphthenic hydrocarbons, aliphatic hydrocarbons such as hexane, cyclohexane, kerosene, and paraffinic hydrocarbons, halogenated (hydro)carbons such as trichloroethylene, tetrachloroethylene, trichlorofluoroethylene, and ethyl bromide, fluorine-containing ether compounds, fluorine-containing ester compounds, and silicone coils. In order to color the dispersion medium, oil-soluble dyes such as anthraquinones and azo-compounds having a desired absorption characteristic are used. Additionally, a surface active agent, etc., may be added to the dispersion liquid for the stabilization of dispersion.

Since the organic EL element is self-emission-type one, vivid full-color displaying can be conducted. Also, the EL layer is a very thin organic film, and therefore, excellent in flexibility, whereby the formation thereof on a flexible substrate is particularly suitable.

The following examples are provided for specifically describing the present invention and the present invention is not limited to these examples.

(Evaluation of Absorption Coefficient)

Polyimide material JALS-2021 (polyimide with a side chain) (available from JSR Corporation) whose surface energy can be changed by irradiation with ultraviolet rays was spin-coated onto a quartz substrate so as to form a film and was baked at 180° C. Next, the film thickness of the polyimide film was obtained by using an atomic force microscope (AFM). Also, an ultraviolet and visible absorption spectrum of the polyimide film was obtained, so that the absorbance thereof at each wavelength was obtained. An absorption coefficient a of the polyimide film at a wavelength of 250 nm (corresponding to the wavelength of an extra-high pressure mercury lamp) was calculated by applying the obtained absorbance to Formula (3).

$$α = \frac{Absorbance}{d log e} \qquad ( 3 )$$

The obtained absorption coefficient α was 1.2×10⁷ [m⁻¹]. Additionally, formula (3) can be derived from Lambert's law, since

$$\begin{matrix}Absorbance = - log T \\ = - log ( I / {I}_{0} ) \\ = α d log e\end{matrix}$$

is satisfied, wherein the intensity of incident light, the intensity of transmitted light, the thickness of an absorbing material, and the transmittance are denoted by I₀, I, d, and T, respectively.

(Evaluation 1 of Insulation Characteristic)

Each of highly-insulating polyimide materials (soluble polyimides) SN-20 (available from New Japan Chemical Co., Ltd.) and JALS-2021 (in regard to the change of wettability thereof, see examples described below.) was spin-coated onto an aluminum evaporated film on a glass substrate so as to form a film and baked at 180° C. The thickness of the obtained film was 200-350 nm. Additionally, the film thickness was measured by a tracer method and an atomic force microscope. Next, the stacked insulating film was irradiated with ultraviolet rays (from an extra-high pressure mercury lamp) while the time period of the irradiation was changed. Further, Au was vacuum-deposited through a metal mask onto the stacked insulating film so as to form an electrode with a diameter of 1 mm. As a voltage was applied, the value of electric current at each voltage was measured. The specific resistance of the polyimide film was obtained from the obtained film thickness in the case of each of ultraviolet ray irradiation energies. The results are shown in Table 2.

TABLE 2

| | | | |
|---|---|---|---|
| Irradiation energy | 0 | 10 | 20 |
| of ultraviolet rays | | | |
| (J/cm²) | | | |
| Specific resistance | 1.7 × 10¹⁵ | 1.4 × 10¹⁴ | 8.2 × 10¹³ |
| of polyimide film | | | |
| (SN-20) (Ωcm) | | | |
| Specific resistance | 1.1 × 10¹² | 5.5 × 10¹¹ | 2.1 × 10¹¹ |
| of polyimide film | | | |
| (JALS-2021) (Ωcm) | | | |

It can be seen from Table 2 that the polyimide film (SN-20) had a high specific resistance, that is, high insulating property, even if the film was formed at 180° C., in the case of no ultraviolet ray irradiation. Also, the specific resistance of any polyimide film became smaller by the ultraviolet ray irradiation and the insulating property thereof decreased. Therefore, it can be considered that the total insulating property of the stacked insulating film could be retained by stacking a wettability control layer, for example, the polyimide film (JALS-20) on an insulating film, for example, a polyimide film (SN-20) and reducing the amount of ultraviolet ray irradiation to the polyimide film (SN-20). That is, when the film thickness of the polyimide film (JALS-2021) became larger, the transmittance of ultraviolet rays was lowered and ultraviolet rays for irradiation of the polyimide film (SN-20) as an underlying layer decreased so as to reduce damage thereof.

(Evaluation 2 of Insulating Characteristic)

SN-20 was spin-coated onto an Al evaporated film on a glass substrate and baked at 180° C. such that the thickness thereof was 350 nm. Next, each of polyimide films (JALS-2021) with various kinds of thicknesses was spin-coated onto the polyimide film (SN-20) and baked at 180° C. Next, the stacked insulating film was irradiated with ultraviolet rays from an extra-high pressure mercury lamp such that the irradiation energy thereof was 20 J/cm². Further, Au was vacuum-deposited through a metal mask onto the stacked insulating film so as to form an electrode with a diameter of 1 mm. Next, a voltage was applied and the value of electric current was measured at each voltage. The specific resistance of the stacked insulating film was obtained from the obtained electric current and film thickness thereof. Additionally, the film thickness was measured by a tracer method and an atomic force microscope.

Separately, a polyimide film (JALS-2021) was similarly formed on a quartz substrate, and the ultraviolet and visible absorption spectrum thereof was measured so as to obtain the transmittance of the polyimide film (JALS-2021).

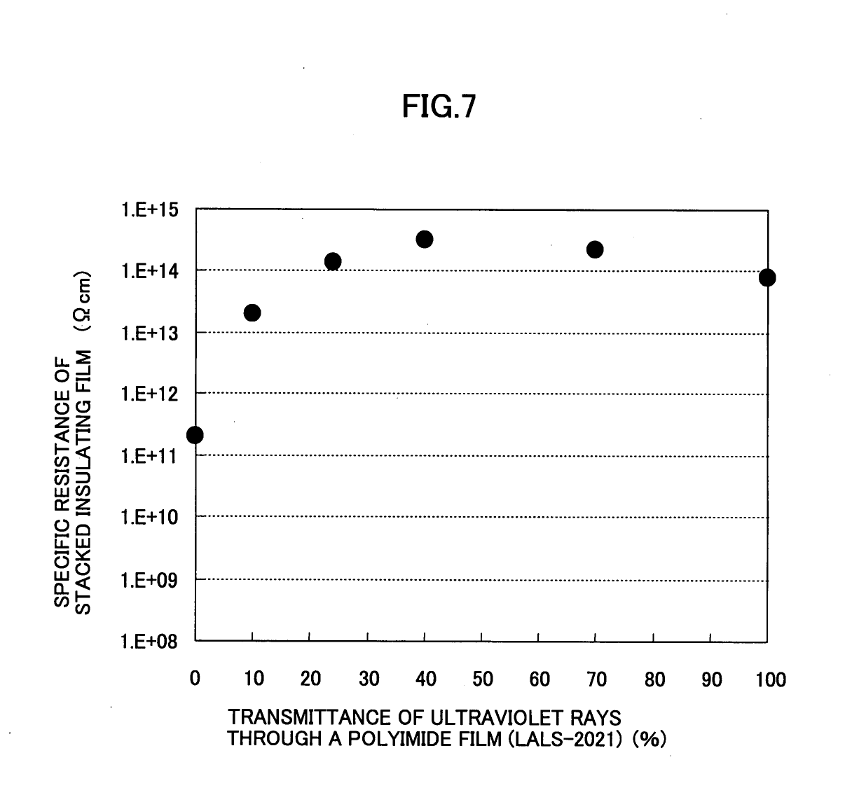

FIG. 7 shows the relationship between the specific resistance of stacked insulating film and the transmittance of ultraviolet rays through a polyimide film (JALS-2021). When the thickness of the polyimide film (JALS-2021) became larger, the transmittance of ultraviolet rays became smaller but the contribution to the specific resistance of the stacked insulating film became larger so that the specific resistance became smaller. Also, when the transmittance in regard to the polyimide film (JALS-2021) was large, the polyimide film (SN-20) as an underlying layer was irradiated with ultraviolet rays and the specific resistance of the stacked insulating film became small. As a result, as the specific resistance of the stacked insulating film was plotted against the transmittance of ultraviolet rays through the polyimide film (JALS-2021), a convex curve having a local maximum value was obtained. It can be seen from FIG. 7 that where the transmittance of ultraviolet rays through the polyimide film (JALS-2021) was less than 10%, in other words, the absorbance of the ultraviolet rays was over 90%, the specific resistance of the stacked insulating film was lowered. This indicates that if the absorbance of ultraviolet rays was 90% or less, the insulating property of the stacked insulating film was retained without deteriorating the insulating property of the underlying polyimide film (SN-20). The transmittance of ultraviolet rays through the polyimide film (JALS-2021) being 10% corresponded to the film thickness being 200 nm. Therefore, it can be seen that when the film thickness of the wettability control layer was 200 nm or less, it was sufficient.

(Evaluation of a Contact Angle of Water)

JALS-2021 and a polyimide material PI-101 (polyimide with a side chain) (available from Maruzen Petrochemical) were spin-coated onto a quartz substrate to form a film and baked at 180° C. The polyimide film with a thickness of 100 nm (JALS-2021) and the polyimide film (PI-101) were irradiated with ultraviolet rays (from an extra-high pressure mercury lamp) such that the irradiation energy was 30 J/cm². Additionally, the film thickness was obtained by a tracer method.

The contact angles of water on the polyimide film (JALS-2021) and polyimide film (PI-101) were obtained by a liquid drop method. The results are shown in Table 3.

TABLE 3

| | Before irradiation | After irradiation |
|---|---|---|
| | of ultraviolet rays | of ultraviolet rays |
| Polyimide film | 95° | 19° |
| (JALS-2021) | | |
| Polyimide film | 84° | 12° |
| (PI-101) | | |

It can be seen from Table 3 that the surface energies of the polyimide film (JALS-2021) and polyimide film (PI-101) were changed by ultraviolet ray irradiation.

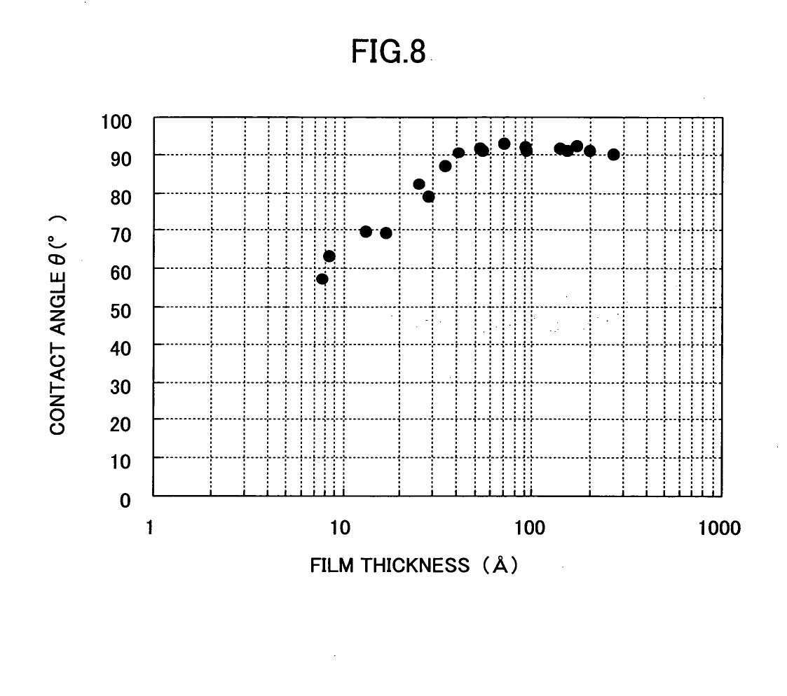

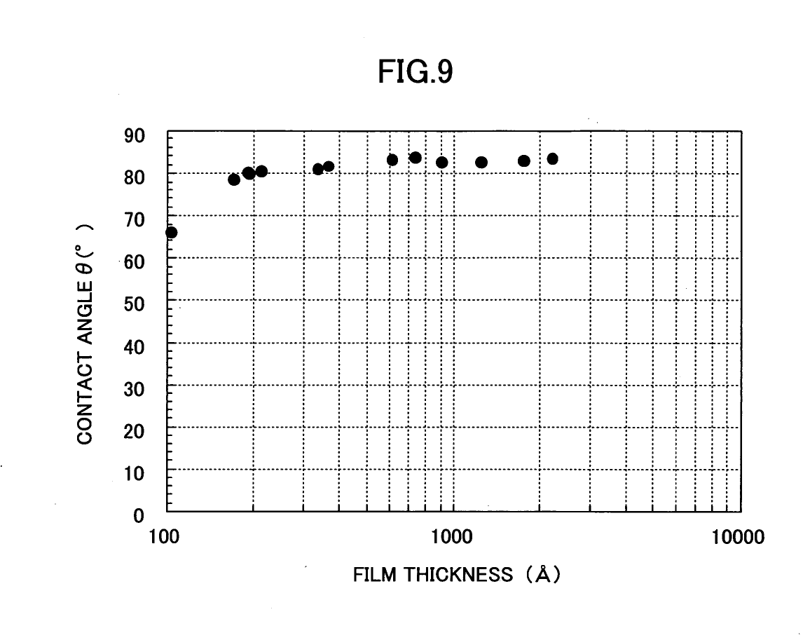

While the conditions of spin-coat film formation were changed, film formation was conducted using JALS-2021 and PI-101, the contact angle of water was measured for each film thickness. Then, when the film thickness was small, the film thickness was obtained by an atomic force microscope (AFM). The results are shown in FIG. 8 and FIG. 9.

It can be seen from FIG. 8 that the contact angle of water on the polyimide film (JALS-2021) decreased with the reduction of the film thickness when the film thickness was less than 40 angstroms, that is, 4 nm. This indicates that the uniformity of the film was degraded and no sufficient water-repellency could be retained, when the film thickness was 4 nm. Therefore, even though the polyimide film (JALS-2021) with a film thickness equal to or less than 4 nm was irradiated with ultraviolet rays, a sufficient change of the contact angle, that is, no sufficient change of the surface energy could be obtained and it was difficult to form an electrode pattern with a good precision.

It can be seen from FIG. 9 that the contact angle of water on the polyimide film (PI-101) decreased with the reduction of the film thickness when the film thickness was less than 200 angstroms, that is, 20 nm. This indicates that the uniformity of the film was degraded and no sufficient water-repellency could be retained, when the film thickness was less than 20 nm. Therefore, even though the polyimide film (PI-101) with a film thickness less than 20 nm was irradiated with ultraviolet rays, a sufficient change of the contact angle, that is, no sufficient change of the surface energy could be obtained and it was difficult to form an electrode pattern with a good precision.

Thus, it can be seen that, when the surface energy was changed by ultraviolet ray irradiation, a certain lower limit is provided with respect to the film thickness.

(Evaluation 3 of Insulating Characteristic)

Each of polyimide films (SN-20) with various kinds of thicknesses was formed on an Al electrode similarly to the above description. Next, a polyimide film (JALS-2021) was stacked thereon. The thickness of the polyimide film (JALS-2021) was 4 nm. An Au electrode was formed similarly to the above description. The electric current—voltage characteristic and film thickness of the stacked insulating film were measured similarly to the above description so as to obtain the specific resistance. The result is shown in FIG. 10. Similarly, the film thickness of the polyimide film (JALS-2021) was also 10 nm and stacked insulating films in which the film thickness of the polyimide film (Sn-20) was changed were formed. The electric current—voltage characteristic and film thickness of the stacked insulating film were measured so as to obtain the specific resistance. The results are shown in FIG. 10.

Additionally, the vertical axis in FIG. 10 shows the ratio of the specific resistance of the stacked insulating film with each film thickness to the specific resistance of the stacked insulating film with a film thickness of 100 nm. When the film thickness of the polyimide film (LALS-2021) was 4 nm, the ratio of the specific resistances increased with the increase of the film thickness of the stacked insulating film, and it was saturated when the film thickness was 50 nm or greater. Also, even when the film thickness of the polyimide film (JALS-2021) was 10 nm, the ratio of the specific resistances increased with the increase of the film thickness of the stacked insulating film and tended to be saturated in case of 50 nm or greater. It can be seen that although there was a difference between the ratio of the specific resistances which was caused by the reduction of the film thickness of the polyimide film (SN-20), a good insulating characteristic could be provided when the film thickness of the stacked insulating film was 50 nm or greater.

(Fabrication of Organic Transistor)

A film of Al was formed on a glass substrate by a vacuum deposition method using a metal mask so as to form a gate electrode with a film thickness of 50 nm.

Similarly to the above description, a polyimide film (JALS-2021) was stacked on a polyimide film (SN-20) with a film thickness of 400 nm so as to form a stacked insulating film (gate insulating film) Then, the film thickness of the polyimide film (JALS-2021) was two kinds, that is, 2 nm and 10 nm.

Ultraviolet ray irradiation through a photomask was conducted by using an extra-high pressure mercury lamp such that the irradiation energy was 20 J/cm², whereby a high surface energy area was formed on the gate insulating film. Silver ink was ejected onto the high surface energy area by using an ink jet method and baked at 200° C. so as to form a source electrode and a drain electrode such that the space between the electrodes was 5 μm and the channel length was 5 μm.

While a triarylamine represented by chemical structural formula 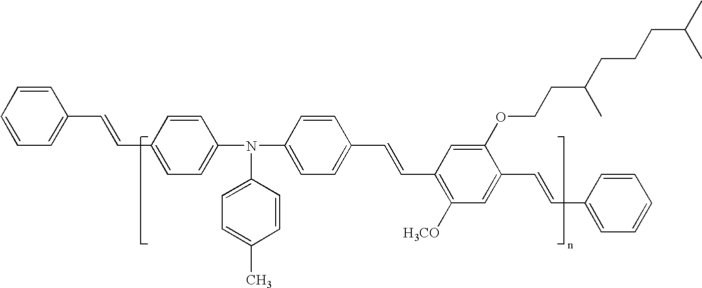
was used as an organic semiconductor material, film formation was conducted by a spin-coat method, so that an organic semiconductor layer with a film thickness of 30 nm was formed and an organic transistor was fabricated.

The configuration of the organic transistor was substrate/gate electrode (Al)/stacked insulating film (gate insulating film)/source electrode and drain electrode (Ag)/organic semiconductor layer (see FIG. 1.).

(Evaluation of Organic Transistor)

The evaluation results of a patterning characteristic and a transistor characteristic are shown in Table 4.

TABLE 4

| | Organic | Organic |
|---|---|---|
| | transistor 1 | transistor 2 |
| Film thickness of polyimide | 2 | 100 |
| film (JALS-2021) (nm) | | |
| Transmittance of ultraviolet | 98 | 28 |
| rays through polyimide film | | |
| (JALS-2021) (%) | | |
| Film thickness of polyimide | 400 | 400 |
| film (SN-20) | | |
| source/drain patterning | No good | Good |
| characteristics | | |
| Field-effect mobility | Unmeasurable | 1 × 10⁻³ |
| (cm²/V · sec) | | |

Additionally, the patterning characteristic was evaluated by observing a pattern using a light microscope.

In regard to the organic transistor 1, since the thickness of the polyimide film (JALS-2021) as a wettability control layer was insufficient, no sufficient contrast could be obtained even if ultraviolet ray irradiation was conducted, and there was a failure in the patterning characteristic such that source and drain lines contact to each other. As a result, no organic transistor could be fabricated.

In regard to the organic transistor 2, the patterning characteristic was good and an organic transistor having a field-effect mobility of 1×10⁻³ cm²/V·sec was obtained. Additionally, this value is comparable, as compared to an organic transistor fabricated by using a source electrode and a drain electrode which are made of Au and formed by a vacuum deposition method using a metal mask.

(Fabrication of a Device having Plural Organic Transistors (see FIG. 5))

A gate electrode 15, an insulating film 12 and a wettability control layer 13 were formed similarly to the above description. A source electrode 16 and a drain electrode 17 were formed by using silver ink similarly to the above description. Finally, an organic semiconductor layer 14 was formed into an island shape by a micro-contact printing method while a solution is used in which the triarylamine represented by the chemical structural formula described above was dissolved in toluene. According to the process described above, a device was fabricated which had a two-dimensional array of 32×32 organic transistors (the pitch between the elements was 500 μm.) on the substrate 11. The field-effect mobility of the plural organic transistors 41 was 1.1×10⁻³ cm²/Vsec.

(Fabrication of Display Device (See FIG.6))

Liquid in which microcapsules containing titanium oxide particles and isoper colored with oil blue were mixed in a PVA aqueous solution was applied on a substrate 52 made of polycarbonate on which a transparent electrode 51 made of ITO was formed, so that a display device 53 composed of the microcapsules and the PVA was formed. The aforementioned device having the plural organic transistors was adhered to the display device 53 on the substrate 52. A driver IC for scanning signal and a driver IC for data signal were connected to a bus line connecting to the gate electrode 15 and a bus line connecting to the source electrode 16, respectively. As images were switched with respect to each 0.5 seconds, a good static image could be displayed.

[Appendix]

Typical embodiments (1) to (6) of the present invention are described below.

Embodiment (1) is an organic transistor having at least a stacked insulating film in which an insulating layer and a wettability control layer are stacked in order, characterized in that the wettability control layer contains a material whose surface energy can be changed by irradiation with an ultraviolet ray and a transmittance of the ultraviolet ray for irradiation therethrough is 10% or greater. According to embodiment (1), there can be provided an organic transistor in which the insulating property of a gate insulating film is good and which is capable of reducing electric power consumption.

Embodiment (2) is the organic transistor as described in embodiment (1) above, characterized in that a film thickness of the wettability control layer is 4 nm or greater and 200 nm or less. According to embodiment (2), an organic transistor in which the insulating property of a gate insulating film is good can be obtained.

Embodiment (3) is the organic transistor as described in embodiment (1) or (2) above, characterized in that a film thickness of the stacked insulating film is 50 nm or greater and 750 nm or less. According to embodiment (3), a good insulating property can be obtained.

Embodiment (4) is the organic transistor as described in any of embodiments (1) to (3) above, characterized in that the stacked insulating film is made of a polymeric material. According to embodiment (4), a production process thereof can be simplified.

Embodiment (5) is the organic transistor as described in any of embodiments (1) to (4) above, characterized in that the wettability control layer is made of a polyimide. According to embodiment (5), a production process thereof can be simplified.

Embodiment (6) is a display device characterized by having at least the organic transistor as described in any of embodiments (1) to (5). According to embodiment (6), there can be provided a display device in which the insulating property of a gate insulating film is good and which is capable of reducing electric power consumption.

The present invention is not limited to the specifically disclosed embodiments, and variations and modifications may be made without departing from the scope of the present invention.

The present application is based on Japanese priority application No. 2005-319691 filed on Nov. 02, 2005 and Japanese priority application No. 2006-213403 filed on Aug. 4, 2006, the entire contents of which are,hereby incorporated by reference.

What is claimed is:

1. An organic transistor comprising a stacked insulating film in which an insulating layer and a wettability control layer are stacked in order, wherein the wettability control layer comprises a material whose surface energy can be changed by irradiation with an ultraviolet ray and a transmittance of the ultraviolet ray for irradiation therethrough is 10% or greater.

2. The organic transistor as claimed in claim 1, wherein a film thickness of the wettability control layer is 4 nm or greater and 200 nm or less.

3. The organic transistor as claimed in claim 1, wherein a film thickness of the stacked insulating film is 50 nm or greater and 750 nm or less.

4. The organic transistor as claimed in claim 1, wherein the stacked insulating film is made of a polymeric material.

5. The organic transistor as claimed in claim 1, wherein the wettability control layer is made of a polyimide.

6. A display device comprising the organic transistor as claimed in claim 1.
